(19) United States
(12) Patent Application Publication
(10) Pub. No.: US 2021/0159056 A1
(43) Pub. Date: May 27, 2021

(54) FOCUS-RING CONVEYING MEMBER AND PLASMA PROCESSING DEVICE INCLUDING FOCUS-RING CONVEYING MEMBER

(71) Applicant: KYOCERA Corporation, Kyoto-shi, Kyoto (JP)

(72) Inventor: Takeshi MUNEISHI, Kusatsu-shi, Shiga (JP)

(21) Appl. No.: 17/047,617

(22) PCT Filed: Apr. 19, 2019
(86) PCT No.: PCT/JP2019/016833

§ 371 Date: Oct. 14, 2020

(30) Foreign Application Priority Data
Apr. 26, 2018 (JP) 2018-085376

(51) Int. Cl. H01J 37/32; B25J 15/06; H02N 13/00

(52) U.S. Cl. CPC H01J 37/32642; B25J 15/06; H02N 13/00; H01J 37/32532; H01J 37/32807

(57) ABSTRACT

A focus-ring conveying member includes a substrate; and a first electrode for electrostatic attraction arranged in the substrate. The plasma processing device according to the present disclosure includes the above-mentioned focus-ring conveying member; a pedestal including a placement surface on which an object to be treated is placed; a focus ring that is arranged to surround the placement surface; and a support member that supports the focus ring. The support member includes a second electrode for electrostatic attraction which is arranged in the support member.

### FIELD

The present disclosure relates to a focus-ring conveying member and a plasma processing device including the focus-ring conveying member.

### BACKGROUND

In a semiconductor manufacturing process, a process (hereinafter, may be referred to as “plasma treatment”) has been executed by a plasma processing device in which a wafer that is an object to be treated is treated by using plasma in a vacuum atmosphere. Herein, the plasma processing device includes a circular focus ring that surrounds an outer periphery of a wafer.

For example, Patent Literature 1 (Japanese Patent Application Laid-open No. 2017-212051) discloses a plasma processing device that includes a focus ring.

### SUMMARY

### Solution to Problem

A focus-ring conveying member according to the present disclosure includes: a substrate; and a first electrode for electrostatic attraction arranged in the substrate.

A plasma processing device according to the present disclosure includes: the above-mentioned focus-ring conveying member; a pedestal including a placement surface on which an object to be treated is placed; a focus ring that is arranged to surround the placement surface; and a support member that supports the focus ring. The support member includes a second electrode for electrostatic attraction which is arranged in the support member.

### BRIEF DESCRIPTION OF DRAWINGS

FIG. 1 is a plan view illustrating one example of a focus-ring conveying member according to the present disclosure.

FIG. 2 is a cross-sectional view obtained by cutting the focus-ring conveying member illustrated in FIG. 1 in a direction perpendicular to a thickness direction thereof.

FIG. 3 is a plan view illustrating another example of the focus-ring conveying member according to the present disclosure.

FIG. 4 is a cross-sectional view taken along a line iv-iv illustrated in FIG. 3.

FIG. 5 is a plan view illustrating positional relation between first protrusion parts of the focus-ring conveying member according to the present disclosure.

FIG. 6 is a rear view illustrating another example of the focus-ring conveying member according to the present disclosure.

FIG. 7 is a cross-sectional view taken along a line vii-vii illustrated in FIG. 6.

FIG. 8 is a cross-sectional view illustrating one example of a plasma processing device according to the present disclosure.

### DESCRIPTION OF EMBODIMENTS

A focus ring is pared off by plasma in repeated treatments so as to be worn. Thus, a focus ring is to be appropriately replaced. In this case, replacement of a focus ring is manually performed by a worker after the inside of a plasma processing device under vacuum atmosphere is returned to a state of atmospheric air, and thus the inside of the plasma processing device needs returning from the atmospheric air to the vacuum atmosphere after the replacement of the focus ring is completed.

As described above, the replacement of a focus ring including a change in the atmosphere takes time so as to be a cause of reduction in production efficiency of a plasma processing device. Thus, there is desired a focus-ring conveying member and a plasma processing device including the focus-ring conveying member capable of replacing a focus ring while reducing reduction in production efficiency.

In accordance with a focus-ring conveying member according to the present disclosure, a focus ring is able to be replaced without changing the atmosphere. In accordance with a plasma processing device according to the present disclosure, a time interval for replacing a focus ring is short, and thus production efficiency is high.

Hereinafter, the focus-ring conveying member according to the present disclosure will be described in detail with reference to the accompanying drawings.

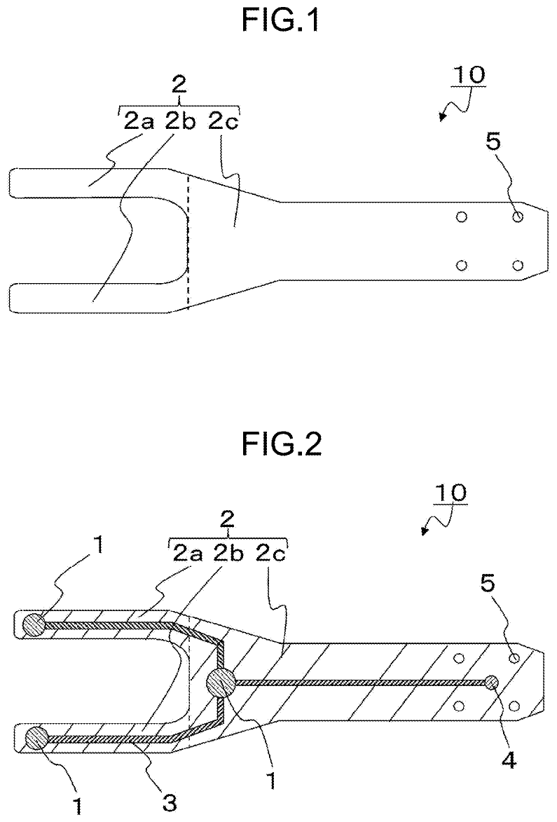

In FIG. 1, there is illustrated one example of a shape in a plan view of a focus-ring conveying member 10 according to the present disclosure. In FIG. 1, there is illustrated a Y-shaped substrate 2 constituted of a base 2c, and a first part 2a and a second part 2b that are bifurcated from the base 2c.

FIG. 2 is a diagram illustrating one example of an internal structure of the focus-ring conveying member 10, and further is a cross-sectional view obtained by cutting the focus-ring conveying member 10 in a direction perpendicular to a thickness direction of the substrate 2. As illustrated in FIG. 2, the focus-ring conveying member 10 includes the substrate 2 and first electrodes 1 for electrostatic attraction that are arranged in the substrate 2. In FIG. 2, a case is exemplified in which the number of the first electrodes 1 is three; however, not limited thereto, it is sufficient that the number of the first electrodes 1 is at least one.

In FIG. 2, a case is exemplified in which each of the first electrodes 1 is constituted of a single electrode, i.e., a unipolar-type one; however, not limited thereto. For example, the first electrode 1 may be constituted of an electrode to which positive voltage is applied and an electrode to which negative voltage is applied, i.e. a bipolar-type one.

The focus-ring conveying member 10 according to the present disclosure includes the first electrodes 1 for electrostatic attraction, and thus when voltage is applied to the first electrodes 1, the substrate 2 is able to attract and hold a focus ring by using electrostatic attraction forces such as the Coulomb force and the Johnson-Rahbeck force. Thus, the focus-ring conveying member 10 according to the present disclosure does not need change in the atmosphere, which is different from the conventional case, and under vacuum atmosphere, the substrate 2 attracts and holds a worn focus ring by using electrostatic attraction so as to convey it, and then similarly conveys and arranges a new focus ring to be able to replace a focus ring.

There also may be a diagram illustrating an example in which electric power is supplied to the three first electrodes 1 from an electric-power supplying part 4 via a wire 3 connecting therebetween. The arrangement of the wire 3 connecting the electric-power supplying part 4 to the first electrodes 1 is not limited to the example illustrated in FIG. 2.

Herein, a focus ring is formed in circular-shaped, and the focus-ring conveying member 10 includes a plane part in a surface (surface illustrated in FIG. 1) thereof corresponding to a part that supports a lower part of the focus ring.

In FIGS. 1 and 2, a case is exemplified in which the focus-ring conveying member 10 includes four connection holes 5 to be connected with a metal shaft of a conveyance device (not illustrated). Note that electric power is supplied to the electric-power supplying part 4 from, not limited to, the inside of the conveyance device, and is supplied from a connected wire.

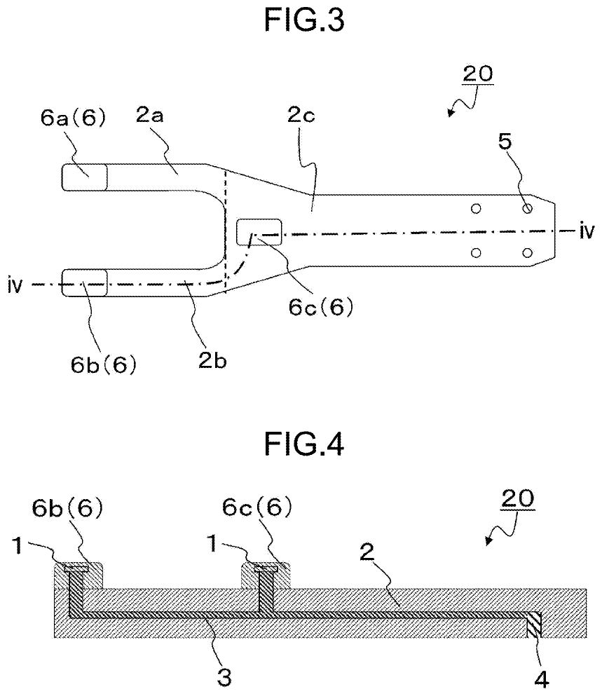

Next, a focus-ring conveying member 20 is illustrated in FIGS. 3 and 4 as another example. As illustrated in the example, the substrate 2 may include first protrusion parts 6 each having a top surface as an attraction surface, and at least a part of the first electrode 1 is arranged in the corresponding first protrusion part 6. Incidentally, an attraction surface means a surface that is in contact with a focus ring so as to attract and hold the focus ring during electrostatic attraction. That at least a part of the first electrode 1 is arranged in the corresponding first protrusion part 6 means that in a state of a perspective plan view, which is illustrated in FIG. 3, a presence position of the first electrode 1 is overlapped with a presence position of the first protrusion part 6.

When such a configuration is satisfied, a top surface of the first protrusion part 6 is an attraction surface, and thus a positional alignment between the top surface of the first protrusion part 6 and the focus ring is easy during electrostatic attraction. Moreover, when an area of a top surface of the first protrusion part 6 to be in contact with a focus ring is smaller than a contact area between the substrate 2 and a focus ring in a case without the first protrusion part 6, damage to a focus ring during electrostatic attraction is able to be reduced.

As illustrated in FIGS. 3 and 4, a top surface of the first protrusion part 6 may be plane, a peripheral portion directing from the top surface toward the substrate 2 may be connected by a curved surface. When such a configuration is satisfied, a top surface of the first protrusion part 6 is plane, and thus the top surface of the first protrusion part 6 is closely in contact with a focus ring during electrostatic attraction, so that it is possible to reduce possibility that a focus ring falls off during replacement of the focus ring. Moreover, a peripheral portion of the first protrusion part 6 is a curved surface, a focus ring and the peripheral portion of the first protrusion part 6 is hardly in contact with each other, so that it is possible to reduce damage to a focus ring during electrostatic attraction.

In the focus-ring conveying members 10 and 20, a shape in a plan view of the substrate 2 may be formed in quadrangular-shaped, round-shaped, or the like, as illustrated in FIGS. 1 to 4, may be formed in Y-shaped constituted of the base 2c, and the first part 2a and the second part 2b that are bifurcated from the base 2c. As indicated in FIGS. 1 to 3 by using a dotted line, a boundary between (i) the first part 2a and the second part 2b and (ii) the base 2c is a part in which the bifurcation begins.

The substrate 2 of the focus-ring conveying members 10 and 20 having such a configuration is formed in Y-shaped, and thus the focus-ring conveying members 10 and 20 are capable of holding a focus ring more stably during electrostatic attraction while they are lighter than that in the case where the shape in the plan view is quadrangle or round, so that it is possible to improve conveyance speed of a focus ring.

As illustrated in FIG. 3, the number of the first protrusion parts 6 in the focus-ring conveying member 20 may be three, and the three first protrusion parts 6 may be respectively arranged at a distal end part of the first part 2a, a distal end part of the second part 2b, and a root connected with the first part 2a and the second part 2b in the base 2c. Specifically, in FIG. 3, there is illustrated an example in which a first protrusion part 6a is arranged at the distal end part of the first part 2a, a first protrusion part 6b is arranged at the distal end part of the second part 2b, and a first protrusion part 6c is arranged at the root of the base 2c.

When a length from a leading end of the first part 2a to a boundary with the base 2c is defined as a first length, the distal end part of the first part 2a indicates a part from a starting point that is the leading end of the first part 2a to a part (end point) corresponding to ⅓ of the first length. On the other hand, when a length from a leading end of the second part 2b to a boundary with the base 2c is defined as a second length, the distal end part of the second part 2b indicates a part from a starting point that is the leading end of the second part 2b to a part corresponding to ⅓ of the second length. When a length from the boundary to a leading end close to the conveyance device is defined as a third length, the root of the base 2c indicates a part from a starting point that is the boundary to a part corresponding to ⅓ of the third length.

The focus-ring conveying member 20 satisfying such a configuration is capable of attracting and holding a focus ring during electrostatic attraction while stabilizing the focus ring with the minimum contact area. In a case where the substrate 2 has such a shape illustrated in FIG. 3, even when there presents a more or less deformed supported part in a focus ring, attraction is able to be performed by using deflection of one or both of the first part 2a and the second part 2b, so that reliability of the attraction is excellent.

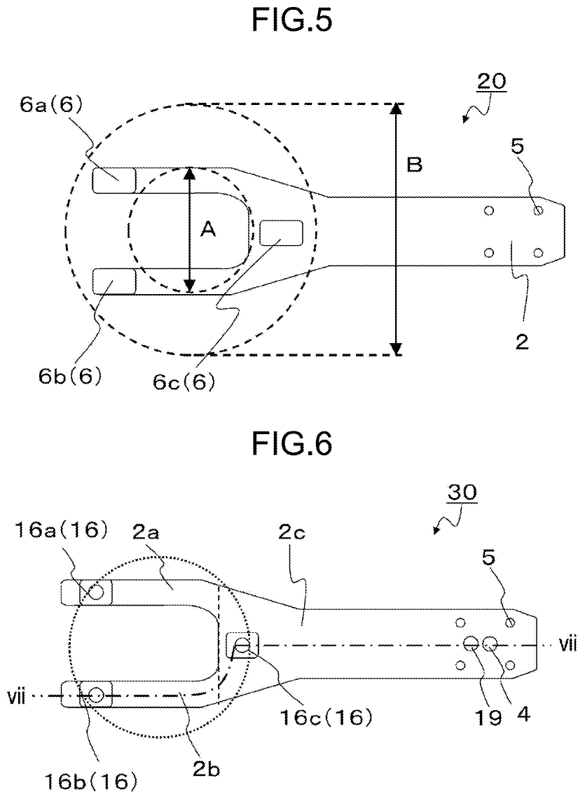

Moreover, as illustrated in FIG. 5, in a plan view, the first protrusion parts 6 may be arranged in an opposed region of a focus ring whose inside diameter is A and further whose outside diameter is B. The opposed region means an area between a small dotted circle and a large dotted circle illustrated in FIG. 5. Being arranged in the opposed region means that in a plan view illustrated in FIG. 5, the first protrusion part 6 is not recognized inside the small circle or outside the large circle.

In the focus-ring conveying member 20 satisfying such a configuration, the first protrusion part 6 is not in contact with a periphery of a focus ring during electrostatic attraction, so that the possibility that a periphery of a focus ring is damaged is small.

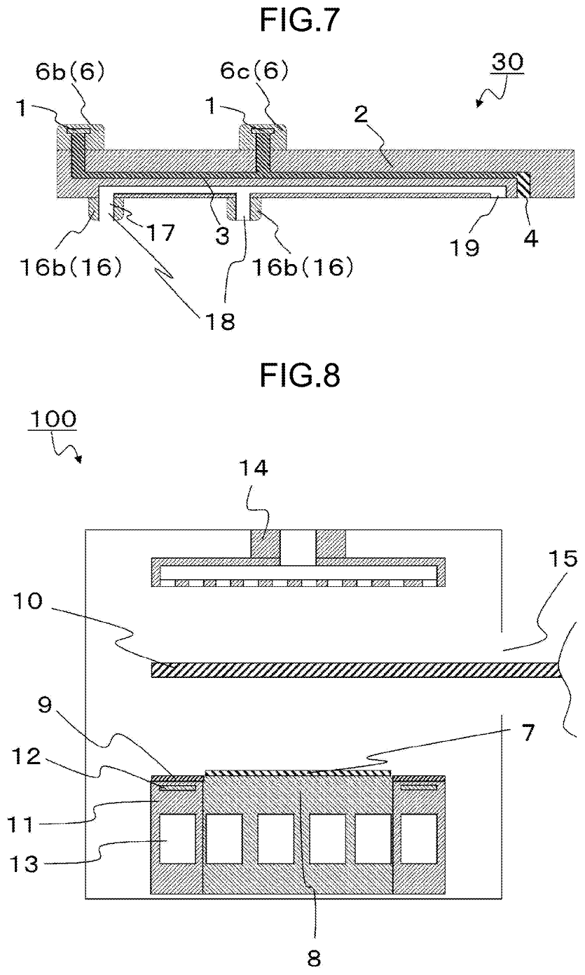

Next, a focus-ring conveying member 30 is illustrated in FIGS. 6 and 7 as another example. As indicated by the example, the substrate 2 may include second protrusion parts 16 arranged on an opposite surface of the surface on which the first protrusion parts 6 are arranged. FIG. 6 is a rear view illustrating an opposite surface of the surface illustrated in FIG. 3. FIG. 7 is a cross-sectional view taken along a line vii-vii illustrated in FIG. 6, and the first protrusion parts 6 are illustrated so as to direct upward, for convenience of explanation of differentiation from FIG. 4.

When such a configuration is satisfied, the second protrusion parts 16 are capable of conveying another conveyance object such as a wafer. When conveying a conveyance object in a placed manner, the substrate 2 may be turned upside down from a state illustrated in FIG. 7 to be used. In this case, it is preferable that the focus-ring conveying member 30 is attached to an arm that is configured to be inverted.

As in the focus-ring conveying member 30 illustrated in FIG. 7, the substrate 2 may further include therein a suction flow path 17, and the second protrusion parts 16 may include suction holes 18 connected with the suction flow path 17. When such a configuration is satisfied, as described above, a conveyance object is able to be conveyed by using attraction caused by suction without inversion. Moreover, in the state illustrated in FIG. 7, the focus-ring conveying member 30 is capable of electrostatically attract a focus ring on an upper part, and is further capable of attract another conveyance object on a lower part, so that it is possible to improve work efficiently.

The aforementioned is merely described on the basis of the illustrated state, and according to the example illustrated in FIG. 3, with respect to electrostatic attraction of a focus ring in practical use, the first protrusion parts 6 face and attract a focus ring, and thus the focus-ring conveying member 30 is used in a state where an upper surface thereof illustrated in FIG. 7 directs downward. Needless to say, the suction flow path 17 is connected to an external suction mechanism via a connection hole 19, a hose, and the like.

The suction flow path 17 and the suction holes 18 may be connected to a vacuum pump to be used for exhausting gas in order to keep degree of vacuum. Moreover, the suction flow path 17 and the suction holes 18 may be connected to a gas supplying device to be used for ejecting gas from the suction holes 18 via the suction flow path 17.

Next, the number of the first protrusion parts 6 may be three or more, the number of the second protrusion parts 16 may be also two or more, on an opposite surface of a surface on which the first protrusion parts 6 are arranged, the centers of the plurality of second protrusion parts 16 may be arranged on an inner side from an imaginary circle surrounded by the centers of the first protrusion parts 16.

In an environment where the focus-ring conveying member 30 is used, a conveyance object other than a focus ring is smaller than the focus ring. Thus, when the centers of the second protrusion parts 16 are arranged on an inner side from an imaginary circle surrounded by the centers of the first protrusion parts 16, the conveyance and the attraction become easy, so that reliability of the conveyance is improved.

Hereinafter, a reference symbol of “10” is provided to a focus-ring conveying member, and explanation will be continued.

The substrate 2 of the focus-ring conveying member 10 according to the present disclosure may be made of ceramic. When such a configuration is satisfied, the ceramic has a high corrosion resistance and a high durability, and thus the focus-ring conveying member 10 according to the present disclosure is able to be used under an atmosphere of a high corrosive gas, a high temperature and a high pressure, etc.

As a ceramic composing the substrate 2, an aluminum-oxide-based ceramic, a silicon-nitride-based ceramic, an aluminum-nitride-based ceramic, a silicon-carbide-based ceramic, or the like may be employed. The aluminum-oxide-based ceramic contains equal to or more than 70% by mass of an aluminum oxide of 100% by mass of all of the components composing the ceramic. The same is applied to other ceramics.

Materials of the substrate 2 may be identified by the following method. First, the substrate 2 is measured by using an X-ray diffractometer (XRD) and identification is executed from a value of an obtained 2θ (where 2θ is diffraction angle) by using a JCPDS card. Herein, a case is exemplified in which presence of an aluminum oxide in the substrate 2 is identified by XRD. Next, quantitative analysis of aluminum (Al) is executed by using an Inductively Coupled Plasma (ICP) emission spectrophotometer or an X-ray fluorescence spectrometer (XRF). When a content obtained by converting a content of aluminum (Al) measured by an ICP or an XRF into aluminum oxide (Al₂O₃) is equal to or more than 70% by mass, the substrate 2 is composed of an aluminum-oxide-based ceramic.

The first protrusion parts 6 of the focus-ring conveying member 10 according to the present disclosure may be made of ceramic. The first protrusion parts 6 may be composed of a ceramic that is different from that of the substrate 2, when the first protrusion parts 6 are composed of a ceramic same as that of the substrate 2, a thermal expansion coefficient of the first protrusion parts 6 is the same as that of the substrate 2, a crack due to difference between the thermal expansion coefficients does not occur, and thus may be used even under an environment whose temperature change is large. That the first protrusion parts 6 are composed of a ceramic same as that of the substrate 2 means that, for example, when the substrate 2 is composed of an aluminum-oxide-based ceramic, the first protrusion parts 6 are also composed of an aluminum-oxide-based ceramic.

It is sufficient that a main component composing the first electrodes 1, the wire 3, and the electric-power supplying part 4 in the focus-ring conveying member 10 according to the present disclosure is metal having the conductivity. Specifically, a main component of the first electrodes 1, the wire 3, and the electric-power supplying part 4 may be molybdenum (Mo), tungsten (W), or platinum (Pt). Herein, the main component is a component of more than 50% by mass of 100% by mass of all of the components composing the first electrodes 1, the wire 3, and the electric-power supplying part 4. When the substrate 2 and/or the first protrusion parts 6 are made of ceramic, the first electrodes 1, the wire 3, and the electric-power supplying part 4 may contain, in addition to metal, an inorganic insulator such as an aluminum oxide (Al₂O₃) and a silicon dioxide (SiO₂) in order to bring a thermal expansion coefficient thereof close to that of a ceramic.

Hereinafter, a plasma processing device 100 according to the present disclosure will be specifically explained with reference to FIG. 8. In the following explanation with respect to FIG. 8, a reference symbol of “10” is provided to a focus-ring conveying member.

As illustrated in FIG. 8, the plasma processing device 100 according to the present disclosure includes the focus-ring conveying member 10 having the above-mentioned configuration, a pedestal 8 including a placement surface on which an object to be treated 7 such as a silicon wafer is placed, a focus ring 9 arranged so as to surround the placement surface, and a support member 11 that supports the focus ring 9. The support member 11 includes a second electrode 12 for electrostatic attraction which is arranged in the support member 11.

The placement surface of the pedestal 8 is a surface that is in contact with the object to be treated 7. In order to fix the object to be treated 7 to the placement surface, it is sufficient that a vacuum chuck, an electrostatic chuck, or the like is provided to at least a part of the placement surface of the pedestal 8, for example.

In the example illustrated in FIG. 8, the pedestal 8 and the support member 11 are separately provided; however, it is sufficient that the support member 11 supports the focus ring 9. For example, the pedestal 8 may include a support part for the focus ring 9, namely, the pedestal 8 and the support member 11 may be integrated with each other.

Similarly to the first electrode 1, the second electrode 12 may be a unipolar-type one constituted of a single electrode, or may be a bipolar-type one constituted of an electrode to which positive voltage is applied and an electrode to which negative voltage is applied.

The plasma processing device 100 according to the present disclosure has such a configuration, and thus when voltage is applied to the second electrode 12 during a plasma treatment, the support member 11 is able to attract and hold the focus ring 9 by using electrostatic attraction forces such as the Coulomb force and the Johnson-Rahbeck force. On the other hand, replacement of the focus ring 9 is executed in accordance with the following procedure. First, voltage is not applied to the second electrode 12 so that the focus ring 9 is able to be detached from the support member 11. Next, the focus-ring conveying member 10 having the above-mentioned configuration is inserted into a conveyance port 15 of the plasma processing device 100, and the focus-ring conveying member 10 attracts and holds the worn focus ring 9 by the electrostatic attraction, and then conveys it to a storing chamber (not illustrated). Next, the worn focus ring 9 is replaced with the new focus ring 9 in the storing chamber, and then the new focus ring 9 is conveyed to be placed on the support member 11. Next, voltage is applied to the second electrode 12 so as to attach the focus ring 9 to the support member 11 by using electrostatic attraction forces. As described above, the plasma processing device 100 according to the present disclosure is capable of executing the above-mentioned replacement of the focus ring 9 without changing the atmosphere, so that replacement of the focus ring 9 does not take time, and thus production efficiency is high.

The plasma processing device 100 according to the present disclosure may include a gas supplying member 14 that supplies desired gas. The gas supplying member 14 may include a high frequency electrode in order to cause it to function as an upper electrode in a plasma treatment. Similarly, the pedestal 8 may include a high frequency electrode in order to cause it to function as a lower electrode in a plasma treatment.

The support member 11 of the plasma processing device 100 according to the present disclosure may include flow paths 13 arranged in the support member 11. At least a part of the flow paths 13 may be arranged under the second electrode 12. In a case where such a configuration is satisfied, when refrigerant flows through the flow paths 13, the focus ring 9 that is heated up in a plasma treatment is able to be rapidly cooled down, and thus replacement of the focus ring 9 is enabled without sparing time from the plasma treatment, so that it is possible to improve production efficiency of the plasma processing device 100 according to the present disclosure.

Similarly to the support member 11, the pedestal 8 may include the flow paths 13 arranged in the pedestal 8. In a case where such a configuration is satisfied, when refrigerant flows through the flow paths 13, a temperature of the object to be treated 7 is able to be controlled during a plasma treatment.

The pedestal 8 and the support member 11 of the focus-ring conveying member 10 according to the present disclosure may be made of ceramic. When such a configuration is satisfied, the ceramic has a high corrosion resistance and a high durability, and thus the pedestal 8 and the support member 11 are able to endure a long-term use in a plasma treatment.

The ceramic composing the pedestal 8 and the support member 11 may be, similarly to the substrate 2, an aluminum-oxide-based ceramic, a silicon-nitride-based ceramic, an aluminum-nitride-based ceramic, a silicon-carbide-based ceramic, or the like.

A main component composing the second electrode 12 may be metal having the conductivity, similarly to the first electrodes 1, the wire 3, and the electric-power supplying part 4.

In the plasma processing device 100 according to the present disclosure, the focus-ring conveying member 10 may convey not only the focus ring 9, but also the object to be treated 7.

Hereinafter, one example of a manufacturing method of the focus-ring conveying member according to the present disclosure will be explained. A case is exemplified in which a substrate of the focus-ring conveying member is composed of ceramic.

A sintering aid, a binder, a solvent, a dispersing agent, and the like are added by predetermined amounts to a raw material powder such as an aluminum oxide (Al₂O₃) powder, a silicon nitride (Si₃N₄) powder, an aluminum nitride (AlN) powder, and a silicon carbide (SiC) powder, and are mixed to fabricate a slurry.

Next, a green sheet is formed from the slurry by the doctor blade method. Or, the slurry is splay-dried by a spray granulation method (spray dry method) to be granulated, and is formed into a green sheet by a roll compacting method.

The obtained green sheet is processed by a well-known method such as laser and a mold so as to obtain a desired shape. In this case, a through hole and/or a groove is formed in the green sheet, and another green sheet is laminated thereon to cover the through hole and the groove by a lamination process to be mentioned later so as to form a suction flow path and a region for arranging a first electrode and a wire. With respect to a first protrusion part, in the example illustrated in FIG. 3, it is sufficient that a green sheet without a through hole is laminated, and a green sheet with a through hole is laminated to form a second protrusion part. A connection hole may be formed such that an opening part thereof is not covered.

Next, a metal member is arranged or conductivity paste is printed on a region of the green sheet on which a first electrode, a wire, and an electric-power supplying part are to be arranged. A main component of the metal member and the conductivity paste is molybdenum (Mo), tungsten (W), or platinum (Pt), for example. In a case of the conductivity paste, an inorganic insulator such as an aluminum oxide (Al₂O₃) and a silicon dioxide (SiO₂) may be added in addition to the above-mentioned metal.

Next, green sheets are laminated by a lamination process to obtain a molded body. The above-mentioned slurry may be used as bonding agent that is used in laminating the green sheets. In the lamination process, a multi-layered structure is easily fabricated, and thus a first electrode is easily formed in, i.e. a bipolar-type one that is constituted of an electrode to which positive voltage is applied and an electrode to which negative voltage is applied.

The obtained molded body is fired in accordance with a firing condition of each raw material powder so as to obtain the focus-ring conveying member according to the present disclosure that includes a first electrode arranged in a substrate thereof.

Note that the pedestal and the support member may be fabricated by a manufacturing method similar to that of the above-mentioned focus-ring conveying member.

### REFERENCE SIGNS LIST

1 First electrode
2 Substrate
2a First part
2b Second part
2c Base
3 wire
4 Electric-power supplying part
5 Connection hole
6, 6a, 6b, 6c First protrusion part
7 Object to be treated
8 Pedestal
9 Focus ring
10 Focus-ring conveying member
11 Support member
12 Second electrode
13 Flow path
14 Gas supplying member
15 Conveyance port
16, 16a, 16b, 16c Second protrusion part
17 Suction flow path
18 Suction hole
19 Connection hole

1. A focus-ring conveying member comprising:
a substrate; and
a first electrode for electrostatic attraction arranged in the substrate.

2. The focus-ring conveying member according to claim 1, wherein
the substrate includes a first protrusion part whose top surface is an attraction surface, and
at least a part of the first electrode is arranged in the first protrusion part.

3. The focus-ring conveying member according to claim 2, wherein
the top surface of the first protrusion part is plane, and
a peripheral portion of the first protrusion part directing from the top surface toward the substrate is connected by a curved surface.

4. The focus-ring conveying member according to claim 2, wherein
the substrate is formed in Y-shaped in a plan view, and is constituted of a base and a first part and a second part that are bifurcated from the base.

5. The focus-ring conveying member according to claim 4, wherein
a number of the first protrusion parts is three, and
the three first protrusion parts are respectively arranged at a distal end part of the first part, a distal end part of the second part, and a root connected with the first part and the second part in the base.

6. The focus-ring conveying member according to claim 2, wherein
in a plan view, the first protrusion part is arranged in an opposed region of a focus ring whose inside diameter is A and further whose outside diameter is B.

7. The focus-ring conveying member according to claim 1, wherein
the first electrode is constituted of an electrode to which positive voltage is applied and an electrode to which negative voltage is applied.

8. The focus-ring conveying member according to claim 2, wherein
the substrate includes a second protrusion part arranged on an opposite surface of a surface on which the first protrusion part is arranged.

9. The focus-ring conveying member according to claim 8, wherein
the substrate includes therein a suction flow path, and
the second protrusion part includes a suction hole connected with the suction flow path.

10. The focus-ring conveying member according to claim 8, wherein
a number of the first protrusion parts is three or more,
a number of the second protrusion parts is two or more, and
on the opposite surface of the surface on which the first protrusion parts are arranged, centers of the plurality of second protrusion parts are arranged on an inner side from an imaginary circle surrounded by centers of the first protrusion parts.

11. The focus-ring conveying member according to claim 1, wherein
the substrate is made of a ceramic.

12. A plasma processing device comprising:
the focus-ring conveying member according to claim 1;
a pedestal including a placement surface on which an object to be treated is placed;
a focus ring that is arranged to surround the placement surface; and
a support member that supports the focus ring, wherein
the support member includes a second electrode for electrostatic attraction which is arranged in the support member.

13. The plasma processing device according to claim 12, wherein
the second electrode is constituted of an electrode to which positive voltage is applied and an electrode to which negative voltage is applied.

14. The plasma processing device according to claim 12, wherein
the support member includes a flow path arranged in the support member, and
at least a part of the flow path is arranged under the second electrode.

15. The plasma processing device according to claim 12, wherein
the pedestal and the support member are made of a ceramic.
